(19) United States
(12) Patent Application Publication
(10) Pub. No.: US 2003/0089952 A1
(43) Pub. Date: May 15, 2003

(54) Method and apparatus for selectively providing a semiconductor device with improved breakdown voltage without requiring an additional mask

(75) Inventors: Shelby F. Nelson, Pittsford, NY (US); Alan D. Raisanen, Sodus, NY (US)

Correspondence Address: Patent Documentation Center, Xerox Corporation, Xerox Sq. 20th Floor, 100 Clinton Avenue South, Rochester, NY, 14644, US

(73) Assignee: Xerox Corporation.

(21) Appl. No.: 10/007,945

(22) Filed: Nov. 13, 2001

(51) Int. Cl. H01L 21/332; H01L 23/62; H01L 29/76; H01L 31/062

(52) U.S. Cl. 257/357; 257/500; 257/509; 257/371

(57) ABSTRACT

The present disclosure relates that by modifying the masking layer normally utilized for complimentary type tub development to provide one or more additional openings arranged in close proximity to the drain area of a selected power device of the non-complimentary type, that the dopant profile may be modified to provide a greater voltage breakdown exclusively for that selected power device without affecting similar type logic circuit non-complimentary devices as found within the same integrated circuit chip. Furthermore, this is accomplished without the need for providing an additional mask or additional process steps to supplement and thereby disturb a given predefined process set for the fabrication of semiconductor devices.

### BACKGROUND OF THE INVENTION AND MATERIAL DISCLOSURE STATEMENT

The present invention relates generally to the fabrication of semiconductor devices. The invention relates more particularly to the enhancement of voltage breakdown levels in power field effect transistors (FET) as integrated with complimentary metal-oxide semiconductor (CMOS) logic without incurring the cost of additional processing steps or masks.

CMOS logic circuits have historically gravitated to ever lower voltage operation. This has happened for many reasons including, for example, lower power dissipation to allow more circuits per chip, and also as the result of shrinking device topography in the effort to improve speed of operation and thereby again increasing circuit density. Most CMOS circuits are typically operated at voltages below 15 volts.

However, while lower voltage rails and power dissipation for the benefit of the logic circuitry are desirable for achieving greater levels of integration, they may be undesirable when interfacing that logic circuitry in its final real world application. This may be true, in particular, when interfacing to integrated on-chip devices as found in MEMS (micro-electrical mechanical) designs. One example of such an integration would be found in driving ink jet printheads which require some power drive to interface with CMOS logic. There is, of course, also great applicability here to common off-chip drivers which share the need for greater power and voltage handling as well. There are many other situations as will be readily apparent to those skilled in the art when the integration of CMOS logic with higher voltage and power operation devices is desirable for interfacing or other circuit chores.

The problem with mixing high voltage power devices with CMOS logic is that additional masks and processing steps are required. This directly affects the cost of such a product and indirectly increases the cost as a result of impacting chip yield as naturally flowing from increased processing complexity. This is to say nothing of the increased process engineering costs incurred in adjusting dopant concentrations and thermal cycles to pre-existing process steps as necessitated with the addition of the new additional processing steps required in order to achieve the high voltage devices.

Therefore, as discussed above, there exists a need for an arrangement which will solve the problem providing high voltage high power devices as integrated with logic devices while minimizing the costs of doing so. Thus, it would be desirable to solve this and other deficiencies and disadvantages as discussed above with an improved semiconductor processing methodology.

### SUMMARY OF THE INVENTION

The present invention relates to an apparatus for providing a higher breakdown voltage to a selected non-complimentary semiconductor device from amongst a quantity of both complimentary and non-complimentary semiconductor devices. The apparatus comprises a wafer for which complimentary and non-complimentary devices are to be provided and a dopant masking layer upon the wafer. The dopant masking layer has normal openings for tub development in accommodation of complimentary devices. The dopant masking layer also has at least one additional opening in proximity to a drain area of the selected non-complimentary device.

In particular, the present invention relates to an apparatus for providing a deeper junction depth and higher breakdown voltage to a selected n-type power device from amongst a quantity of CMOS devices. The apparatus comprises a p-type wafer upon which CMOS devices are to be provided and a dopant masking layer upon the wafer. The dopant masking layer has normal openings for n-type tub development in accommodation of complimentary p-type devices. The dopant masking layer also has at least one additional opening in proximity to a drain area for the selected n-type power device.

The present invention also relates to a method for providing a higher breakdown voltage to a selected semiconductor device from amongst a quantity of semiconductor devices found upon a wafer. The method comprises providing on the wafer a dopant masking layer having for the selected device at least one additional opening in the dopant masking layer in close proximity to a drain area for the selected semiconductor device. The dopant masking layer has normal openings for the development of complimentary device tubs. The method then further comprises doping the wafer.

### BRIEF DESCRIPTION OF THE DRAWINGS

FIG. 1 depicts the first step of note for the semiconductor processing followed in one methodology embodying the present disclosure.

FIG. 2 depicts the result after a process step providing a phosphorus implant.

FIG. 3 shows the result of growing oxide over all regions not previously masked by nitride.

FIG. 4 depicts the resulting p-tub dopant profile after a drive-in anneal and the implantation of boron.

FIG. 5 shows an intermediate result in the continuation of a standard twin tub processes.

FIG. 6 depicts gate oxide growth and polysilicon deposition.

FIG. 7 depicts the result of a drift implant.

FIG. 8 shows a finished device following source and drain implants, reflow of phospho-silicate glass, application of contact metals, and passivation and shows the dopant profile result for the device when additional openings in the n-tub are utilized.

FIG. 9 shows the dopant profile result for the device of FIG. 8 when additional openings are not utilized in the n-tub.

### DESCRIPTION OF THE INVENTION

It is essential to the accomplishment of the integration of typical CMOS logic circuits with higher voltage/power devices that the breakdown voltage V_{bd} of the power devices be sufficient to withstand the higher supply voltages required for their operation. This is achieved by increasing the barrier to electrical breakdown by increasing the amount of isolation region provided.

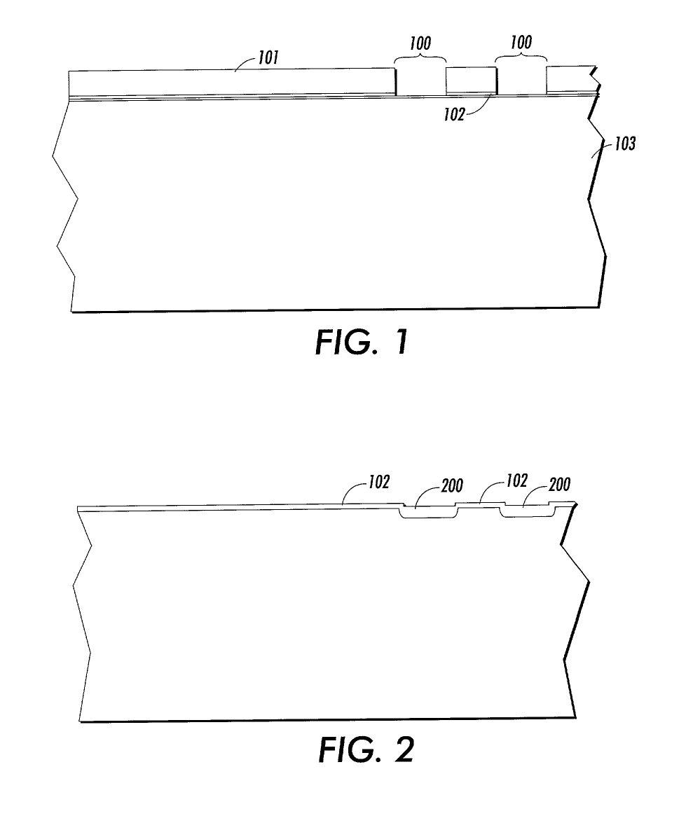

FIG. 1 depicts the first step of note for the semiconductor processing en followed in one methodology embodying the present disclosure, in this instance that is to build an n-type power device (the non-complimentary device in this embodiment) in a twin tub CMOS process. Here in FIG. 1 an n-tub (also known as an n-well) photo-mask has been used to photolithographically develop the photo-resist layer 101 and subsequently open the nitride layer 102 so as act as a masking layer for subsequent dopant implantation. Normally, the whole p-tub region 103 is covered for the implantation of phosphorus for the n-tub so as to accommodate the complimentary devices. In this embodiment, we open up two additional small openings 100 over the eventual position of the power-driver drain. This allows a region of the p-tub 103 to become n-type. These small openings 100 are in addition to the normal openings provided in the n-type regions for the development of the p-type transistors utilized in the CMOS logic area.

In an alternative embodiment, opening 100 may be a single opening or any number of smaller holes utilized so as to most optimally adjust the doping levels by adjusting their size, number and distribution. The choice of the arrangement and position of holes is limited by the design of the driver. If the hole 100 is too large, or too close to what will become the driver's gate, then the device can be shorted out, or have too low a breakdown. The idea is to keep the enhanced n-type region just where it is needed, under the drain of the power driver. In this embodiment, the small openings 100 are approximately 2 microns across and are located approximately 2 microns away from each other edge to edge.

In FIG. 2 there is depicted the result after a process step providing phosphorus implant 200 for the eventual achievement of an n-tub. The photo-resist mask layer 101 has been stripped away prior to the result depicted in FIG. 2 as well.

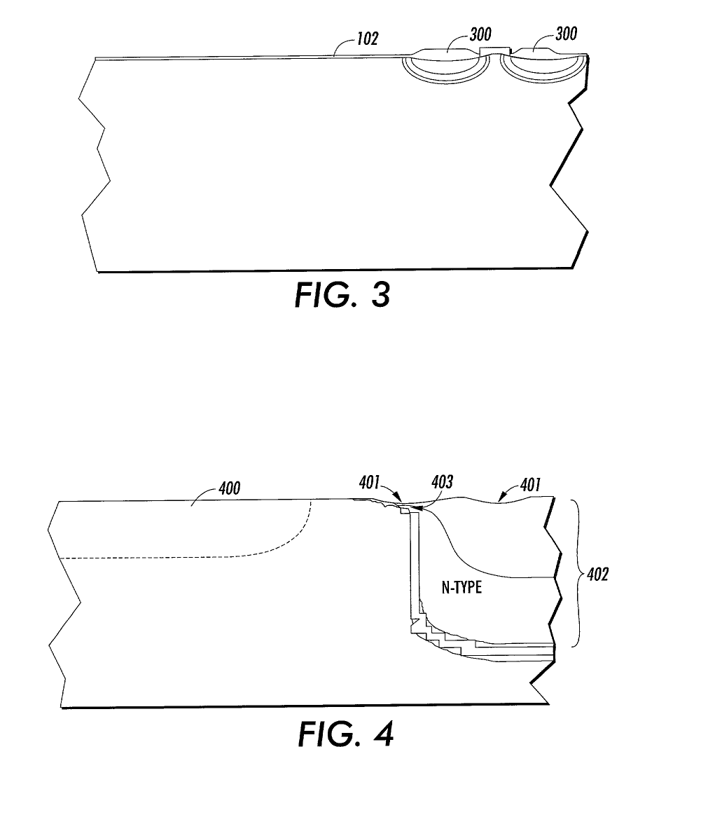

The next step performed, the result of which is shown in FIG. 3, is to grow oxide over all regions not masked by nitride 102 in the step depicted in FIG. 1. This means that oxide 300 is grown over all “n-tub” regions, including those defined by the openings 100 over what is to ultimately become the power driver drain. The growth of thermal oxide 300 uses up silicon, causing the oxide layer 300 to grow below the surface of the nitride protected silicon. As will be explained further in the text below, this creates a distinguishing feature for this device.

FIG. 4 depicts the resulting p-tub 400 after a drive-in anneal, and the implantation of boron. The boron goes directly into silicon anywhere the n-tub oxide doesn't exist, but gets trapped in the oxide over n-tub regions. After implant, the oxide is etched off, leaving distinguishing surface feature “dips” or “dimples” 401 over what will become the power driver drain region 402 (as well as a small step or birds-beak 403 at the usual p-tub/n-tub interfaces, which is common in the art).

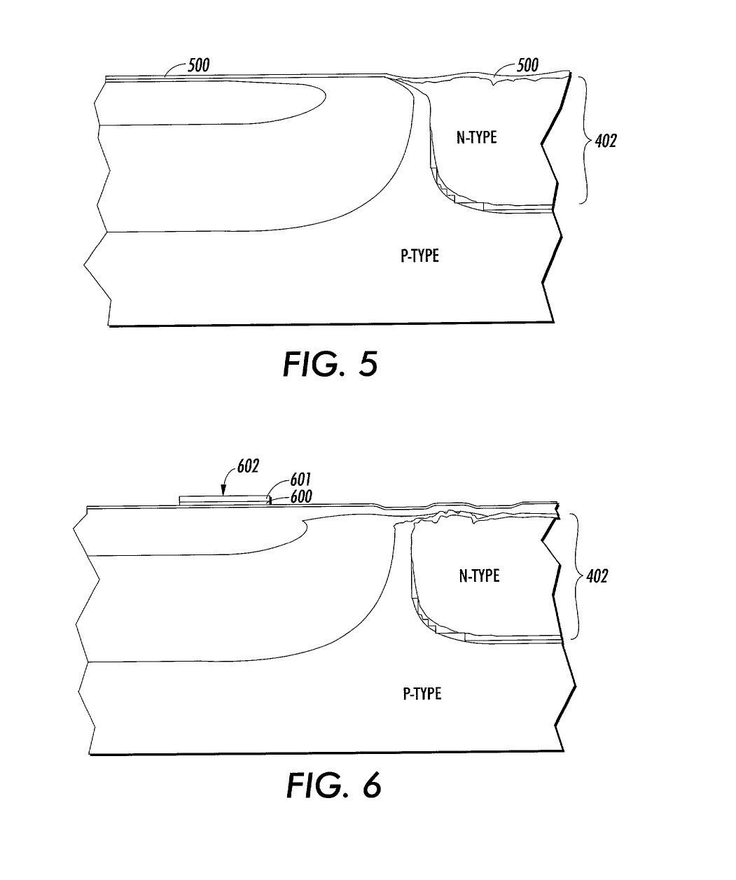

FIG. 5 shows an intermediate result from the continuation of what is otherwise a standard twin tub processes. Because the processing is otherwise conventional, as will be well understood by those skilled in the art not all of the intervening steps have been shown, though they have actually been performed in this embodiment such as: channel-stop implants, growth of field oxide, and sacrificial oxide. Channel implant 500 is then deposited as a blanket of boron in this embodiment, turning the surface of power driver region all p-type again.

In FIG. 6 the gate oxide 600 is grown, and polysilicon 601 is deposited everywhere. The polysilicon 601 is then patterned for gates and etched, resulting in gate 602.

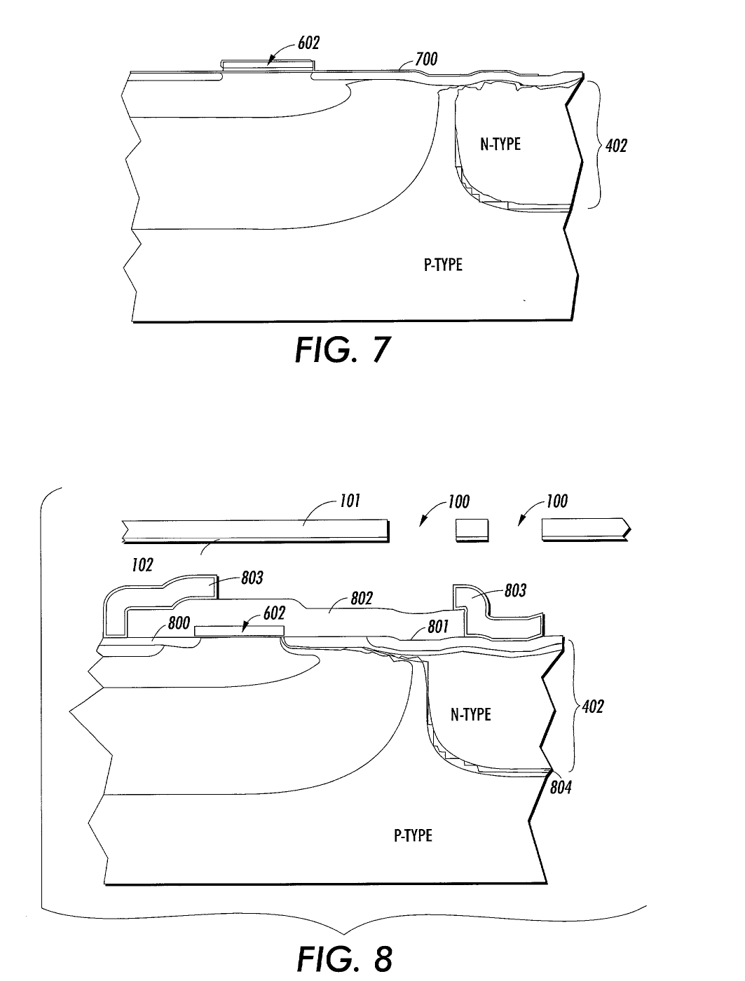

FIG. 7 depicts the result of the Drift implant. In this embodiment, phosphorus is implanted as a blanket, in order to dope the “lightly-doped drift” region 700 between gate 602 and drain region 402 in the power driver.

In FIG. 8 the finished device is shown following source 800 and drain 801 implants, reflow of phospho-silicate glass 802, application of contact metals 803, and passivation. It should be noted that the resulting device has a much deeper junction 804 under the power driver drain than would otherwise occur. This is in contrast to the logic parts of any circuits fabricated with the above described process but without additional openings 100 in the n-tub mask and which thereby retain drain dopant profiles completely standard in depth and behavior.

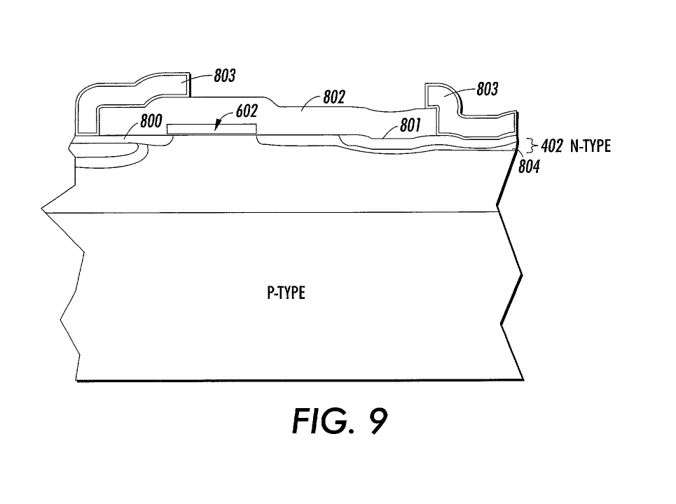

FIGS. 8 and 9 depict and contrast the resulting dopant profile when additional openings in the n-tub masking layer are used as in FIG. 8 on an n-type power device, or as not used as shown in FIG. 9. FIG. 8 shows the dopant profile resulting when additional openings 100 are utilized and the deeper depth junction 804 that is thereby achieved. To clarify that relationship in FIG. 8, an overlay of the masking layer 101 provided with additional openings 100 is suspended above the final resultant cross-section to provide visual correspondence of cause and effect. FIG. 9 shows the otherwise same device employing the same processing steps. However, with additional openings 100 absent, the result is a conventional dopant profile with the junction 804 considerably shallower in profile as is shown.

The exact number and relationship between additional openings 100 and the target power device drain is somewhat empirical in nature, being dependent upon the actual semiconductor process utilized and the device geometry involved. However, software application packages well known in the industry, such as those provided by Silvaco or as provided by Avanti with their TSUPREM4 and Medici software, will readily enable the practitioner skilled in the art and armed with the teachings provided herein to simulate and model without undue iteration the optimum size for openings 100, their relationship to the device, as well as their number and proximity to one another so as to achieve a given desired dopant profile and thereby the breakdown voltage. For example, for the above-described process and mask geometry embodiment, simulation results predicted a V_{bd} of 88 volts versus an actual measured 79 volts for the improved fabricated device of FIG. 8, and a simulated V_{bd} of 48 volts versus 42-45 volts measured in actual fabricated samples for the convention device depicted in FIG. 9.

While the disclosure above has been in terms of a p-type substrate using n-type tubs provided therein for the accommodation of complimentary devices, it will be abundantly clear to those skilled in the art that the teachings provided herein are just as applicable to an arrangement where there is a n-type substrate where p-type tubs are utilized to achieve a complimentary device. It will be further apparent to those skilled in the art that the above disclosure is applicable to single tub on a doped substrate processes or to a technology of twin tubs or wells on a lightly doped substrate. For example where an n-type power device (in a p-tub) is enhanced simultaneously with the development of n-tubs for the accommodation of p-type devices and vice versa. It will also be clearly apparent to those skilled in the art that while the embodiment disclosed herein has been directed to a silicon CMOS process, that the teachings are just as applicable to other complimentary semiconductor venues as, for example, gallium arsenide, germanium, or silicon on insulator.

In closing, by modifying the masking layer normally utilized for complimentary type tub development to provide one or more additional openings arranged in close proximity to the drain area of a selected power device of the non-complimentary type, the dopant profile may be modified to provide a greater voltage breakdown exclusively for that selected power device without affecting similar type logic circuit non-complimentary devices as found within the same integrated circuit chip. Furthermore, this is accomplished without the need for providing an additional mask or additional process steps to supplement and thereby disturb a given predefined process set for the fabrication of semiconductor devices.

While the embodiments disclosed herein are preferred, it will be appreciated from this teaching that various alternative, modifications, variations or improvements therein may be made by those skilled in the art. For example, it is well understood by those skilled in the art that there are many different dopants and methods to implant them to make semiconductor devices, including: direct ion-implantation, exposure in gaseous environment or by direct deposit of a dopant material upon the wafer. There are also many ways known to those skilled in the art in which to effectively provide a masking layer, for example: using photo-masks or direct write techniques. All such variants of processing technique are intended to be encompassed by the following claims:

1. An apparatus for providing a higher breakdown voltage to a selected non-complimentary semiconductor device from amongst a quantity of both complimentary and non-complimentary semiconductor devices comprising:
a wafer for which complimentary and non-complimentary devices are to be provided; and
a dopant masking layer upon the wafer, the dopant masking layer having normal openings for tub development in accommodation of complimentary devices, the dopant masking layer having at least one additional opening in proximity to a drain area of the selected non-complimentary device.

2. The apparatus of claim 1 wherein the wafer is p-type.

3. The apparatus of claim 1 wherein the non-complimentary device is a p-type power device.

4. The apparatus of claim 1 wherein the non-complimentary device is a n-type power device.

5. The apparatus of claim 1 wherein the wafer is n-type.

6. The apparatus of claim 4 wherein the at least one opening is two openings.

7. The apparatus of claim 3 wherein the openings are two microns across and two microns apart edge to edge.

8. The apparatus of claim 1 wherein the complimentary and non-complimentary devices are gallium arsenide based.

9. The apparatus of claim 1 wherein the complimentary and non-complimentary devices are silicon based.

10. An apparatus for providing a deeper junction depth and higher breakdown voltage to a selected n-type power device from amongst a quantity of CMOS devices comprising:
a p-type wafer upon which CMOS devices are to be provided; and
a dopant masking layer upon the wafer, the dopant masking layer having normal openings for n-type tub development in accommodation of complimentary p-type devices, the dopant masking layer having at least one additional opening in proximity to a drain area for the selected n-type power device.

11. The apparatus of claim 10 wherein the at least one additional opening is comprised of two openings.

12. The apparatus of claim 11 wherein the openings are two microns across and two microns apart edge to edge.

13. The apparatus of claim 10 wherein the at least one additional opening is comprised of three openings.

14. An apparatus for providing a deeper junction depth and higher breakdown voltage to a selected p-type power device from amongst a quantity of CMOS devices comprising:
a n-type wafer upon which CMOS devices are to be provided; and
a dopant masking layer upon the wafer, the dopant masking layer having normal openings for p-type tub development in accommodation of complimentary n-type devices, the dopant masking layer having at least one additional opening in proximity to a drain area for the selected p-type power device.

15. The apparatus of claim 14 wherein the at least one additional opening is comprised of two openings.

16. The apparatus of claim 15 wherein the openings are two microns across and two microns apart edge to edge.

17. A method for providing a higher breakdown voltage to a selected semiconductor device from amongst a quantity of semiconductor devices found upon a wafer comprising:
providing on the wafer a dopant masking layer having for the selected device at least one additional opening in the dopant masking layer in close proximity to a drain area for the selected semiconductor device, the dopant masking layer having normal openings for the development of complimentary device tubs; and
doping the wafer.

18. The method of claim 17 wherein the devices are gallium arsenide based.

19. The method of claim 17 wherein the devices are silicon based.

20. The method of claim 17 wherein the wafer is p-type.

21. The method of claim 20 wherein the non-complimentary device is a p-type power device.

22. The method of claim 21 wherein the non-complimentary device is a n-type power device.

23. The method of claim 22 wherein the at least one opening is two openings.

24. The method of claim 23 wherein the openings are two microns across and two microns apart edge to edge.

25. The method of claim 22 wherein the at least one opening is three openings.
